(19) United States
(12) Patent Application Publication
(10) Pub. No.: US 2022/0376128 A1
(43) Pub. Date: Nov. 24, 2022

(54) IMAGING DEVICE AND ELECTRONIC APPARATUS

(71) Applicant: SONY SEMICONDUCTOR SOLUTIONS CORPORATION, KANAGAWA (JP)

(72) Inventor: TAKASHI ITO, TOKYO (JP)

(21) Appl. No.: 17/753,881

(22) PCT Filed: Jul. 13, 2020
(86) PCT No.: PCT/JP2020/027238

§ 371 Date: Mar. 17, 2022

(30) Foreign Application Priority Data
Sep. 27, 2019 (JP) 2019-176817

(51) Int. Cl. H01L 31/113; H01L 31/0224

(52) U.S. Cl. CPC H01L 31/113; H01L 31/022408

(57) ABSTRACT

Provided are an imaging device and an electronic apparatus capable of suppressing deterioration in performance due to charge accumulation. An imaging device includes: a photoelectric conversion layer having a first surface and a second surface located on an opposite side to the first surface; a first electrode located on a side of the first surface; and a second electrode located on a side of the second surface. In a thickness direction of the photoelectric conversion layer, when a region overlapping with the first electrode is defined as a first region, and a region deviating from the first electrode is defined as a second region, a first film thickness of the photoelectric conversion layer in at least a part of the first region is thinner than a second film thickness of the photoelectric conversion layer in the second region.

### TECHNICAL FIELD

The present disclosure relates to an imaging device and an electronic apparatus.

### BACKGROUND ART

A structure is known in which a light shielding layer is disposed in a photoelectric conversion layer on a floating diffusion (hereinafter, FD) electrode so as not to generate charges on the FD electrode (see, for example, FIGS. 41 to 44 of Patent Document 1).

### CITATION LIST

### Patent Document

### Patent Document 1: Japanese Patent Application Laid-Open No. 2017-157816

### SUMMARY OF THE INVENTION

### Problems to be Solved by the Invention

When light is obliquely incident on a surface of a photoelectric conversion layer, light may also be obliquely incident on the photoelectric conversion layer covered with a light shielding layer and disposed on the FD electrode, and charges may be generated and accumulated. In a case where a material contained in the photoelectric conversion layer has a small absorption coefficient, the photoelectric conversion layer may be thickened to increase an absorption ratio. However, when the photoelectric conversion layer is thickened, generation of charges due to obliquely incident light is more remarkable. When charges are accumulated in the photoelectric conversion layer on the FD electrode, there is a possibility that global shutter (GS) driving is inhibited.

The present disclosure has been made in view of such a circumstance, and an object of the present disclosure is to provide an imaging device and an electronic apparatus capable of suppressing deterioration in performance due to charge accumulation.

### Solutions to Problems

An imaging device according to an aspect of the present disclosure includes: a photoelectric conversion layer having a first surface and a second surface located on an opposite side to the first surface; a first electrode located on a side of the first surface; and a second electrode located on a side of the second surface. In a thickness direction of the photoelectric conversion layer, when a region overlapping with the first electrode is defined as a first region, and a region deviating from the first electrode is defined as a second region, a first film thickness of the photoelectric conversion layer in at least a part of the first region is thinner than a second film thickness of the photoelectric conversion layer in the second region. According to this, the imaging device can suppress photoelectric conversion and charge accumulation above the first electrode. The imaging device can suppress deterioration in performance due to charge accumulation above the first electrode.

### BRIEF DESCRIPTION OF DRAWINGS

FIG. 1 is a cross-sectional view schematically illustrating a configuration example of an imaging device according to a first embodiment of the present disclosure.

FIG. 2 is a circuit diagram schematically illustrating a configuration example of the imaging device according to the first embodiment of the present disclosure.

FIG. 3 is a cross-sectional view schematically illustrating a configuration example of a photoelectric conversion unit of the imaging device according to the first embodiment of the present disclosure and a peripheral portion thereof.

FIG. 4A is a cross-sectional view illustrating a method 1 for manufacturing the imaging device according to the first embodiment of the present disclosure in order of steps.

FIG. 4B is a cross-sectional view illustrating the method 1 for manufacturing the imaging device according to the first embodiment of the present disclosure in order of steps.

FIG. 4C is a cross-sectional view illustrating the method 1 for manufacturing the imaging device according to the first embodiment of the present disclosure in order of steps.

FIG. 4D is a cross-sectional view illustrating the method 1 for manufacturing the imaging device according to the first embodiment of the present disclosure in order of steps.

FIG. 4E is a cross-sectional view illustrating the method 1 for manufacturing the imaging device according to the first embodiment of the present disclosure in order of steps.

FIG. 4F is a cross-sectional view illustrating the method 1 for manufacturing the imaging device according to the first embodiment of the present disclosure in order of steps.

FIG. 4G is a cross-sectional view illustrating the method 1 for manufacturing the imaging device according to the first embodiment of the present disclosure in order of steps.

FIG. 4H is a cross-sectional view illustrating the method 1 for manufacturing the imaging device according to the first embodiment of the present disclosure in order of steps.

FIG. 4I is a cross-sectional view illustrating the method 1 for manufacturing the imaging device according to the first embodiment of the present disclosure in order of steps.

FIG. 5A is a cross-sectional view illustrating a method 2 for manufacturing the imaging device according to the first embodiment of the present disclosure in order of steps.

FIG. 5B is a cross-sectional view illustrating the method 2 for manufacturing the imaging device according to the first embodiment of the present disclosure in order of steps.

FIG. 5C is a cross-sectional view illustrating the method 2 for manufacturing the imaging device according to the first embodiment of the present disclosure in order of steps.

FIG. 5D is a cross-sectional view illustrating the method 2 for manufacturing the imaging device according to the first embodiment of the present disclosure in order of steps.

FIG. 5E is a cross-sectional view illustrating the method 2 for manufacturing the imaging device according to the first embodiment of the present disclosure in order of steps.

FIG. 5F is a cross-sectional view illustrating the method 2 for manufacturing the imaging device according to the first embodiment of the present disclosure in order of steps.

FIG. 6 is a cross-sectional view schematically illustrating a configuration example of a photoelectric conversion unit of an imaging device according to a second embodiment of the present disclosure and a peripheral portion thereof.

FIG. 7 is a cross-sectional view schematically illustrating a configuration example of a photoelectric conversion unit of an imaging device according to a third embodiment of the present disclosure and a peripheral portion thereof.

FIG. 8 is a cross-sectional view schematically illustrating a configuration example of a photoelectric conversion unit of an imaging device according to a fourth embodiment of the present disclosure and a peripheral portion thereof.

FIG. 9 is a cross-sectional view schematically illustrating a configuration example of a photoelectric conversion unit of an imaging device according to a fifth embodiment of the present disclosure and a peripheral portion thereof.

FIG. 10 is a block diagram illustrating a configuration example of an imaging device according to a sixth embodiment of the present disclosure.

FIG. 11 is a conceptual diagram illustrating an example in which the technology according to the present disclosure (present technology) is applied to an electronic apparatus.

FIG. 12 is a diagram illustrating an example of a schematic configuration of an endoscopic surgical system.

FIG. 13 is a block diagram illustrating examples of functional configurations of a camera head and a CCU.

FIG. 14 is a block diagram illustrating an example of a schematic configuration of a vehicle control system.

FIG. 15 is an explanatory diagram illustrating examples of installation positions of a vehicle external information detection unit and an imaging unit.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs. However, it should be noted that the drawings are schematic, and a relationship between a thickness and a plane dimension, a ratio between the thicknesses of layers, and the like are different from actual ones. Therefore, specific thicknesses and dimensions should be determined in consideration of the following description. Furthermore, it is a matter of course that the drawings include portions having different dimensional relationships and ratios from each other.

Furthermore, the definitions of directions such as up and down in the following description are merely definitions for convenience of description, and do not limit the technical idea of the present disclosure. For example, it is a matter of course that when an object is observed by rotating the object by 90°, the description is read by converting upper and lower sides into left and right sides, and when the object is observed by rotating the object by 180°, the description is read by inverting the upper and lower sides.

Furthermore, in the following description, a direction may be described using words of an X-axis direction, a Y-axis direction, and a Z-axis direction. For example, the Z-axis direction is a thickness direction of a photoelectric conversion layer 15 described later. The X-axis direction and the Y-axis direction are directions orthogonal to the Z-axis direction. The X-axis direction, the Y-axis direction, and the Z-axis direction are orthogonal to each other. In the following description, a direction parallel to the X-axis direction and the Y-axis direction is also referred to as a horizontal direction.

### First Embodiment

(Overall Structure)

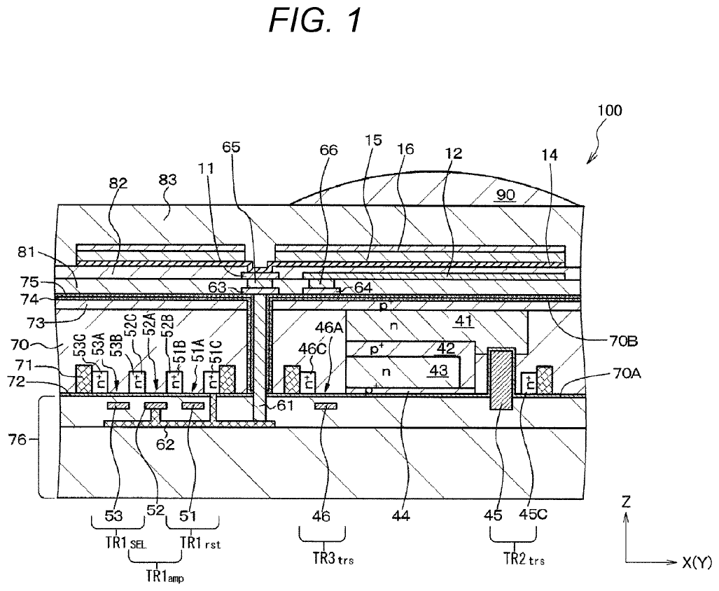

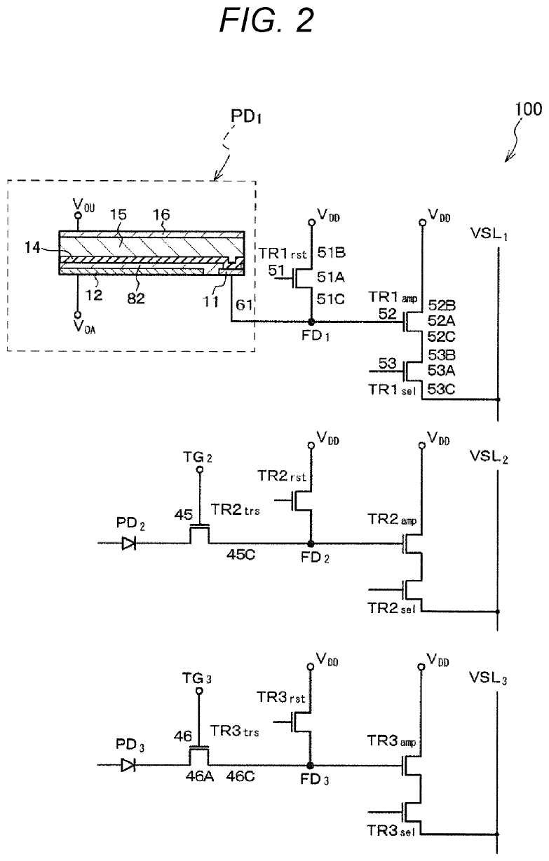

FIG. 1 is a cross-sectional view schematically illustrating a configuration example of an imaging device 100 according to a first embodiment of the present disclosure. FIG. 2 is a circuit diagram schematically illustrating a configuration example of the imaging device 100 according to the first embodiment of the present disclosure. The imaging device 100 according to the first embodiment is, for example, a back irradiation type laminated solid-state imaging device. The imaging device 100 includes, for example, a green imaging element having sensitivity to green light, a blue imaging element having sensitivity to blue light, and a red imaging element having sensitivity to red light.

For example, the red imaging element and the blue imaging element are disposed in a semiconductor substrate 70. The blue imaging element is located so as to be closer to a light incident side than the red imaging element. Furthermore, the green imaging element is disposed above the blue imaging element. The green imaging element, the blue imaging element, and the red imaging element constitute one pixel. No color filter is disposed.

The green imaging element includes a photoelectric conversion unit PD1 formed by laminating a first electrode 11, a photoelectric conversion layer 15, and a second electrode 16. The photoelectric conversion unit PD1 further includes a third electrode 12 disposed apart from the first electrode 11 and facing the photoelectric conversion layer 15 via an insulating layer 82. The third electrode 12 is an electrode for charge accumulation. The photoelectric conversion unit PD1 is disposed above the semiconductor substrate 70.

The first electrode 11 and the third electrode 12 are formed apart from each other on an interlayer insulating film 81. The interlayer insulating film 81 and the third electrode 12 are covered with the insulating layer 82. The insulating layer 82 is an example of a “second insulating layer” in the present disclosure. The photoelectric conversion layer 15 is formed on the insulating layer 82, and the second electrode 16 is formed on the photoelectric conversion layer 15. The third electrode 12 overlaps with the photoelectric conversion layer 15 in a thickness direction (for example, the Z-axis direction) of the photoelectric conversion layer 15. An insulating layer 83 is formed on the entire surface including the second electrode 16. An on-chip micro lens 90 is disposed on the insulating layer 83.

Each of the first electrode 11, the second electrode 16, and the third electrode 12 is constituted by a light-transmissive conductive film. Examples of the light-transmissive conductive film include indium tin oxide (ITO).

The photoelectric conversion layer 15 is constituted by a layer containing an organic photoelectric conversion material having sensitivity to at least green. Examples of the organic photoelectric conversion material having sensitivity to green include a rhodamine-based dye, a melacyanine-based dye, a quinacridone derivative, and a subphthalocyanine-based dye (subphthalocyanine derivative).

Alternatively, the photoelectric conversion layer 15 may contain an inorganic material. Examples of the inorganic material (hereinafter, inorganic photoelectric conversion material) contained in the photoelectric conversion layer 15 include crystalline silicon, amorphous silicon, microcrystalline silicon, crystalline selenium, amorphous selenium, a chalcopyrite-based compound such as CIGS(CuInGaSe), CIS(CuInSe₂), CuInS₂, CuAlS₂, CuAlSe₂, CuGaS₂, CuGaSe₂, AgAlS₂, AgAlSe₂, AgInS₂, or AgInSe₂, a group III-V compound such as GaAs, InP, AlGaAs, InGaP, AlGaInP, or InGaAsP, and a compound semiconductor such as CdSe, CdS, In₂Se₃, In₂S₃, Bi₂Se₃, Bi₂S₃, ZnSe, ZnS, PbSe, or PbS. In addition, quantum dots containing these materials can also be used for the photoelectric conversion layer.

The interlayer insulating film 81 and the insulating layers 82 and 83 each contain a known insulating material (for example, SiO₂ or SiN).

The imaging device 100 further includes a control unit disposed on the semiconductor substrate 70 and having a drive circuit to which the first electrode 11 is connected. A light incident surface in the semiconductor substrate 70 is defined as an upper side, and a side of the semiconductor substrate 70 opposite to the light incident surface is defined as a lower side. A wiring layer 62 including a plurality of wiring lines is disposed below the semiconductor substrate 70.

The third electrode 12 is connected to the drive circuit. For example, the third electrode 12 is connected to the drive circuit via a connection hole 66, a pad portion 64, and wiring VOA disposed in the interlayer insulating film 81. The third electrode 12 is larger than the first electrode 11.

An element isolation region 71 and an oxide film 72 are formed on a side of a front surface 70A of the semiconductor substrate 70. Moreover, on the side of the front surface 70A of the semiconductor substrate 70, a reset transistor TR1rst, an amplification transistor TR1amp, a selection transistor TR1sel, and a first floating diffusion layer FD1 constituting the control unit of the green imaging element are disposed. The reset transistor TR1rst, the amplification transistor TR1amp, and the selection transistor TR1sel constitute the drive circuit.

The reset transistor TR1rst includes a gate portion 51, a channel formation region 51A, a drain region 51B, and a source region 51C. The gate portion 51 of the reset transistor TR1rst is connected to a reset line. The source region 51C of the reset transistor TR1rst also serves as the first floating diffusion layer FD1. The drain region 51B is connected to a power source VDD.

The first electrode 11 is connected to the source region 51C (first floating diffusion layer FD1) of the reset transistor TR1rst via a connection hole 65 and a pad portion 63 formed in the interlayer insulating film 81, a contact hole portion 61 formed in the semiconductor substrate 70 and an interlayer insulating film 76, and the wiring layer 62 formed in the interlayer insulating film 76.

The amplification transistor TR1amp includes a gate portion 52, a channel formation region 52A, a drain region 52B, and a source region 52C. The gate portion 52 is connected to the first electrode 11 and the source region 51C (first floating diffusion layer FD1) of the reset transistor TR1rst via the wiring layer 62. Furthermore, the drain region 52B shares a region with the drain region 51B of the reset transistor TR1rst and is connected to the power source VDD.

The selection transistor TR1sel includes a gate portion 53, a channel formation region 53A, a drain region 53B, and a source region 53C. The gate portion 53 is connected to a selection line. Furthermore, the drain region 53B shares a region with the source region 52C of the amplification transistor TR1amp. The source region 53C is connected to a signal line (data output line) VSL1.

The blue imaging element includes an n-type semiconductor region 41 disposed in the semiconductor substrate 70 as a photoelectric conversion layer of a photoelectric conversion unit PD2. A gate portion 45 of a transfer transistor TR2trs constituted by a vertical transistor extends to the n-type semiconductor region 41 and is connected to a transfer gate line TG2. Furthermore, a second floating diffusion layer FD2 is disposed in a region 45C of the semiconductor substrate 70 near the gate portion 45 of the transfer transistor TR2trs. Charges accumulated in the n-type semiconductor region 41 are read out to the second floating diffusion layer FD2 via a transfer channel formed along the gate portion 45.

In the blue imaging element, on the side of the front surface 70A of the semiconductor substrate 70, a reset transistor TR2rst, an amplification transistor TR2amp, and a selection transistor TR2sel constituting the control unit of the blue imaging element are further disposed.

The reset transistor TR2rst includes a gate portion, a channel formation region, a drain region, and a source region. The gate portion of the reset transistor TR2rst is connected to a reset line. The drain region of the reset transistor TR2rst is connected to the power source VDD. The source region of the reset transistor TR2rst also serves as the second floating diffusion layer FD2.

The amplification transistor TR2amp includes a gate portion, a channel formation region, a drain region, and a source region. The gate portion of the amplification transistor TR2amp is connected to the source region (second floating diffusion layer FD2) of the reset transistor TR2rst. Furthermore, the drain region of the amplification transistor TR2amp shares a region with the drain region of the reset transistor TR2rst, and is connected to the power source VDD.

The selection transistor TR2sel includes a gate portion, a channel formation region, a drain region, and a source region. The gate portion of the selection transistor TR2sel is connected to a selection line. Furthermore, the drain region of the selection transistor TR2sel shares a region with the source region of the amplification transistor TR2amp. The source region of the selection transistor TR2sel is connected to a signal line (data output line) VSL2.

The red imaging element includes an n-type semiconductor region 43 disposed in the semiconductor substrate 70 as a photoelectric conversion layer of a photoelectric conversion unit PD3. A gate portion 46 of the transfer transistor TR3trs is connected to a transfer gate line TG3. Furthermore, a third floating diffusion layer FD3 is disposed in a region 46C of the semiconductor substrate 70 near the gate portion 46 of the transfer transistor TR3trs. Charges accumulated in the n-type semiconductor region 43 are read out to the third floating diffusion layer FD3 via a transfer channel 46A formed along the gate portion 46.

In the red imaging element, on the side of the front surface 70A of the semiconductor substrate 70, a reset transistor TR3rst, an amplification transistor TR3amp, and a selection transistor TR3sel constituting the control unit of the red imaging element are further disposed.

The reset transistor TR3rst includes a gate portion, a channel formation region, and a source/drain region. The gate portion of the reset transistor TR3rst is connected to a reset line. The drain region of the reset transistor TR3rst is connected to the power source VDD. The source region of the reset transistor TR3rst also serves as the third floating diffusion layer FD3.

The amplification transistor TR3amp includes a gate portion, a channel formation region, a drain region, and a source region. The gate portion of the amplification transistor TR3amp is connected to the source region (third floating diffusion layer FD3) of the reset transistor TR3rst. Furthermore, the drain region of the amplification transistor TR3amp shares a region with the drain region of the reset transistor TR3rst, and is connected to the power source VDD.

The selection transistor TR3sel includes a gate portion, a channel formation region, a drain region, and a source region. A gate portion of the selection transistor TR3sel is connected to a selection line. Furthermore, the drain region of the selection transistor TR3sel shares a region with the source region of the amplification transistor TR3amp. The source region of the selection transistor TR3sel is connected to a signal line (data output line) VSL3.

A p⁺ layer 44 is disposed between the n-type semiconductor region 43 and the front surface 70A of the semiconductor substrate 70 to suppress generation of a dark current. A p⁺layer 42 is formed between the n-type semiconductor region 41 and the n-type semiconductor region 43. A part of a side surface of the n-type semiconductor region 43 is surrounded by the p⁺ layer 42. A p⁺ layer 73 is formed on a side of a back surface 70B of the semiconductor substrate 70. A HfO₂ film 74 and an insulating film 75 are formed from the p⁺ layer 73 to the inside of the contact hole portion 61. In the interlayer insulating film 76, wiring (not illustrated) is formed over a plurality of layers.

(Structure of Photoelectric Conversion Unit and Peripheral Portion Thereof)

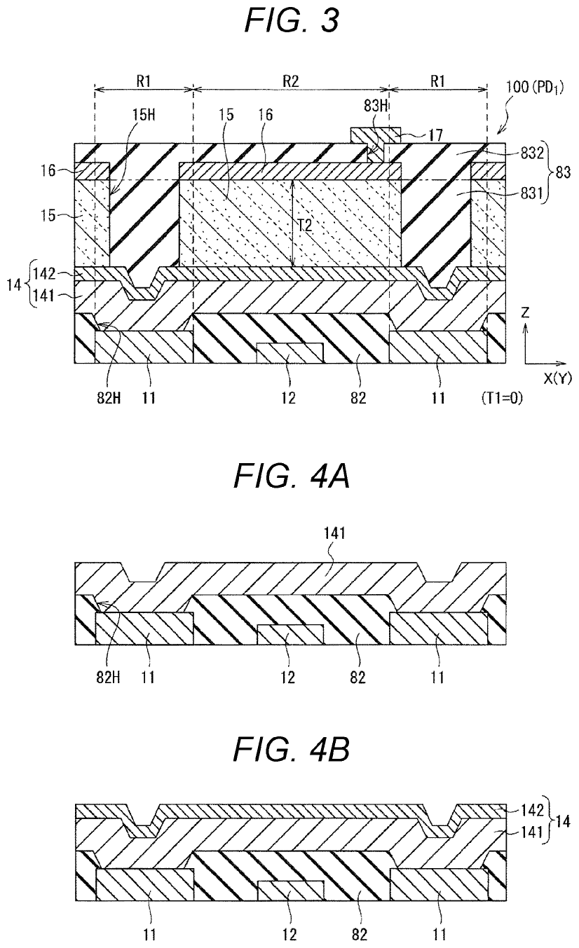

FIG. 3 is a cross-sectional view schematically illustrating a configuration example of the photoelectric conversion unit PD1 of the imaging device 100 according to the first embodiment of the present disclosure and a peripheral portion thereof. In FIG. 3, the first electrode 11, the third electrode 12, and the insulating layer 82 are disposed on the interlayer insulating film 81 (see FIG. 1). The first electrode 11 is an electrode connected to a floating diffusion (for example, the first floating diffusion layer FD1 illustrated in FIG. 1) disposed on the semiconductor substrate 70 (see FIG. 1). The third electrode 12 is covered with the insulating layer 82. Furthermore, in the insulating layer 82, a through hole 82H is formed. The through hole 82H is located on the first electrode 11.

As illustrated in FIG. 3, a conductive layer 14 is disposed on the insulating layer 82. The conductive layer 14 includes, for example, a semiconductor layer 141 and a buffer layer 142 laminated on the semiconductor layer 141. The semiconductor layer 141 is a layer having functions of charge accumulation and transfer. The semiconductor layer 141 is in contact with the first electrode 11. The buffer layer 142 is in contact with the photoelectric conversion layer 15. The photoelectric conversion layer 15 and the insulating layer 83 are disposed on the buffer layer 142.

The semiconductor layer 141 contains a semiconductor material having a large bandgap value (for example, a value of a band gap of 3.0 eV or more) and having a higher mobility than the material contained in the photoelectric conversion layer 15. Examples of such a semiconductor material include: an oxide semiconductor material such as IGZO; a transition metal dichalcogenide; silicon carbide; diamond; graphene; a carbon nanotube; and an organic semiconductor material such as a condensed polycyclic hydrocarbon compound or a condensed heterocyclic compound.

In a case where charges to be accumulated are electrons, the semiconductor layer 141 may contain a material having an ionization potential larger than an ionization potential of the material contained in the photoelectric conversion layer 15. Furthermore, in a case where the charges to be accumulated are holes, the semiconductor layer 141 may contain a material having an electron affinity smaller than an electron affinity of the material contained in the photoelectric conversion layer 15.

The semiconductor layer 141 preferably has an impurity concentration of 1×10¹⁸ cm⁻³ or less. The semiconductor layer 141 may have a single layer structure or a multilayer structure.

The buffer layer 142 has at least one of a function of smoothly transferring electrons from the photoelectric conversion layer 15 to the semiconductor layer 141 and a function of blocking holes from the semiconductor layer 141.

By disposing the semiconductor layer 141 and the buffer layer 142 between the first electrode 11 and the photoelectric conversion layer 15, recombination during charge accumulation can be prevented, and transfer efficiency of charges accumulated in the photoelectric conversion layer 15 to the first electrode 11 can be increased. Furthermore, generation of a dark current can be suppressed.

The photoelectric conversion layer 15 has a first surface 15A and a second surface 15B located on an opposite side to the first surface 15A. The first surface 15A is in contact with the buffer layer 142, and the second surface is in contact with the second electrode 16. As illustrated in FIG. 3, in a thickness direction (for example, the Z-axis direction) of the photoelectric conversion layer 15, a region overlapping with the first electrode 11 is defined as a first region R1, and a region deviated from the first electrode 11 (that is, a region not overlapping with the first electrode 11) is defined as R2. A film thickness T1 (an example of a “first film thickness” in the present disclosure) of the photoelectric conversion layer 15 in at least a part of the first region R1 is thinner than a film thickness T2 (an example of a “second film thickness” in the present disclosure) of the photoelectric conversion layer 15 in the second region R2. For example, the film thickness T1 is zero.

In this example, the photoelectric conversion layer 15 is not disposed in at least a part of a region overlapping with the first electrode 11 in the Z-axis direction (in FIG. 3, above the first electrode 11). As illustrated in FIG. 3, a through hole 15H formed in the photoelectric conversion layer 15 is formed above the first electrode 11.

The insulating layer 83 includes a first insulating film 831 and a second insulating film 832 laminated on the first insulating film 831. The first insulating film 831 is an example of a “first insulating layer” in the present disclosure. The first insulating film 831 is disposed in the first region R1. For example, the first insulating film 831 is disposed in the through hole 15H formed in the photoelectric conversion layer 15. The first insulating film 831 is in contact with the photoelectric conversion layer 15 in the horizontal direction.

The second electrode 16 is disposed in the first region R1. The second insulating film 832 covers the first insulating film 831 and the second electrode 16. Furthermore, in the second insulating film 832, a through hole 83H is formed. Wiring 17 is disposed on the second insulating film 832. The wiring 17 is connected to the second electrode 16 through the through hole 83H.

(Manufacturing Method)

The imaging device 100 is manufactured using various devices such as a film forming device (including a chemical vapor deposition (CVD) device and a sputtering device), an exposure device, an etching device, an ion implantation device, a heat treatment device, a chemical mechanical polishing (CMP) device, and a bonding device. Hereinafter, these devices are collectively referred to as manufacturing devices. The photoelectric conversion unit PD1 and a peripheral portion thereof illustrated in FIG. 3 can be manufactured by a manufacturing method 1 or 2 described next.

(Manufacturing Method 1)

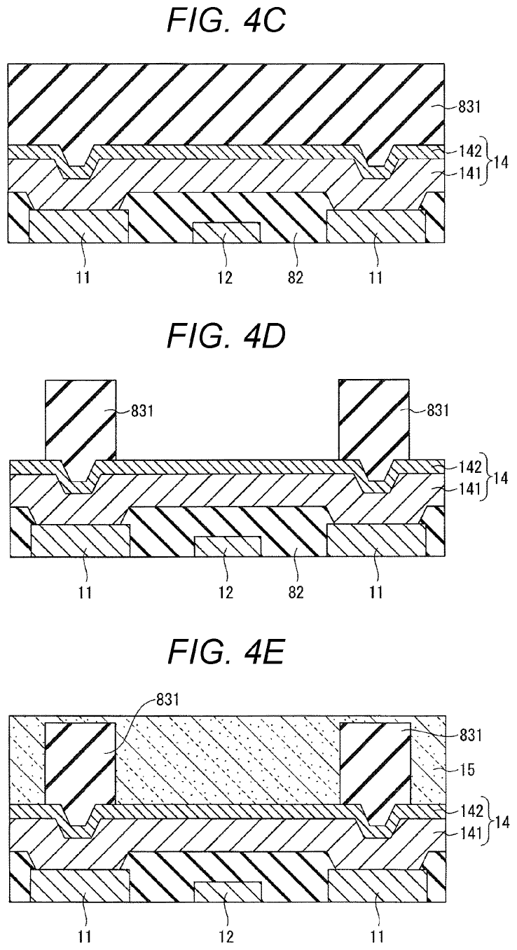

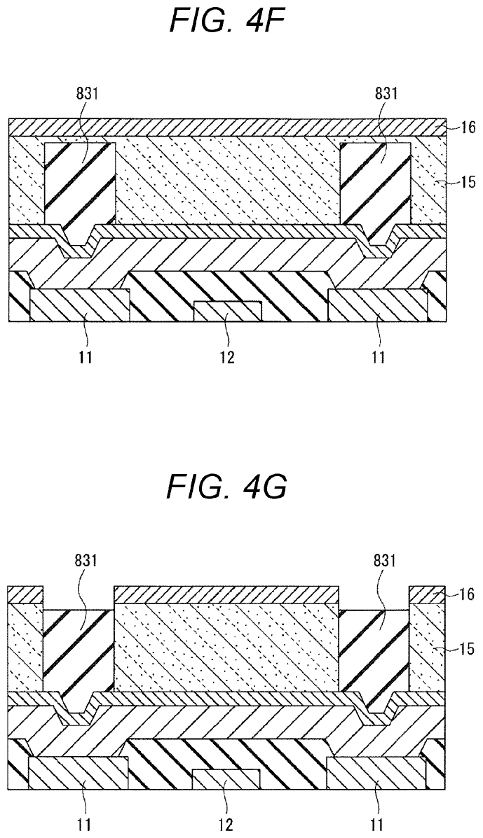

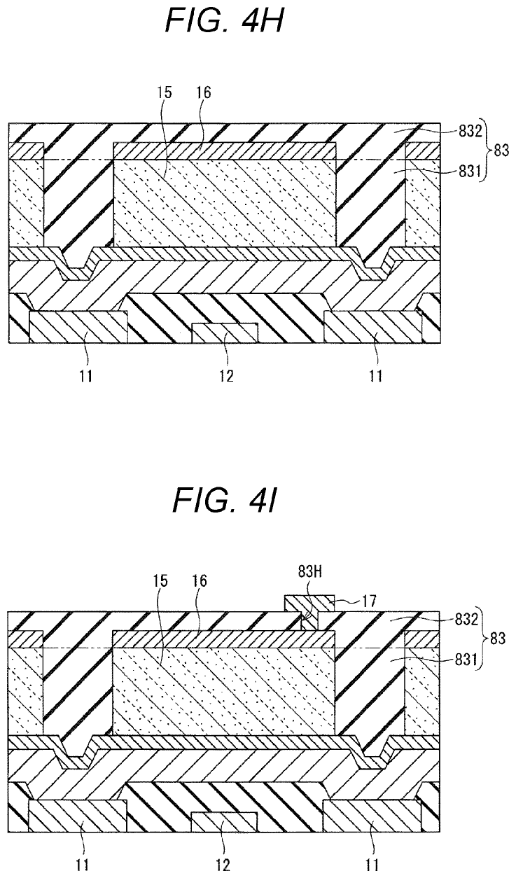

FIGS. 4A to 41 are cross-sectional views illustrating the method 1 for manufacturing the imaging device 100 according to the first embodiment of the present disclosure in order of steps. In FIG. 4A, the manufacturing device forms the first electrode 11 and the third electrode 12 on the interlayer insulating film 81 (see FIG. 1). Next, the manufacturing device forms the insulating layer 82 on the interlayer insulating film 81 on which the first electrode 11 and the third electrode 12 are formed. Next, the manufacturing device locally etches the insulating layer 82 to form the through hole 82H.

Next, the manufacturing device forms a conductive layer (semiconductor layer before patterning) on the insulating layer 82 in which the through hole 82H is formed. Next, the manufacturing device patterns the conductive layer into a predetermined shape using a photolithography technique and an etching technique. Therefore, the semiconductor layer 141 is formed from the conductive layer.

Next, the manufacturing device forms a conductive layer (buffer layer before patterning) on the semiconductor layer 141. Next, the manufacturing device patterns the conductive layer into a predetermined shape using a photolithography technique and an etching technique. Therefore, as illustrated in FIG. 4B, the buffer layer 142 is formed from the conductive layer. Next, as illustrated in FIG. 4C, the manufacturing device forms the first insulating film 831 on the buffer layer 142.

Next, as illustrated in FIG. 4D, the manufacturing device patterns the first insulating film 831 into a predetermined shape using a photolithography technique and an etching technique. In this step, the manufacturing device leaves the first insulating film 831 above the first electrode 11, and removes the first insulating film 831 from the other region. In this step, the buffer layer 142 under the first insulating film 831 functions as an etching stopper for the first insulating film 831.

Next, as illustrated in FIG. 4E, the manufacturing device forms the photoelectric conversion layer 15 on the buffer layer 142. In this step, the manufacturing device forms the photoelectric conversion layer 15 so as to be thicker than the first insulating film 831. Therefore, an upper surface and a side surface of the first insulating film 831 are covered with the photoelectric conversion layer 15.

Next, as illustrated in FIG. 4F, the manufacturing device forms the second electrode 16 on the photoelectric conversion layer 15. Next, as illustrated in FIG. 4G, the manufacturing device patterns the second electrode 16 and the photoelectric conversion layer 15 using a photolithography technique and an etching technique.

Next, as illustrated in FIG. 4H, the manufacturing device forms the second insulating film 832 so as to cover the second electrode 16 and the first insulating film 831 exposed from below the second electrode 16. The second insulating film 832 is laminated on the first insulating film 831 to obtain the insulating layer 83.

Next, as illustrated in FIG. 4I, the manufacturing device forms the through hole 83H in the second insulating film 832 using a photolithography technique and an etching technique. Next, the manufacturing device forms a conductive layer on the second insulating film 832 in which the through hole 83H is formed. Next, the manufacturing device patterns the conductive layer using a photolithography technique and an etching technique. Therefore, the wiring 17 connected to the second electrode 16 through the through hole 83H is formed. Through the above steps, the imaging device 100 illustrated in FIG. 3 is completed.

In the above manufacturing method 1, since the photoelectric conversion layer 15 is formed in a self-aligned manner by the first insulating film 831, etching damage to the photoelectric conversion layer 15 is small.

(Manufacturing Method 2)

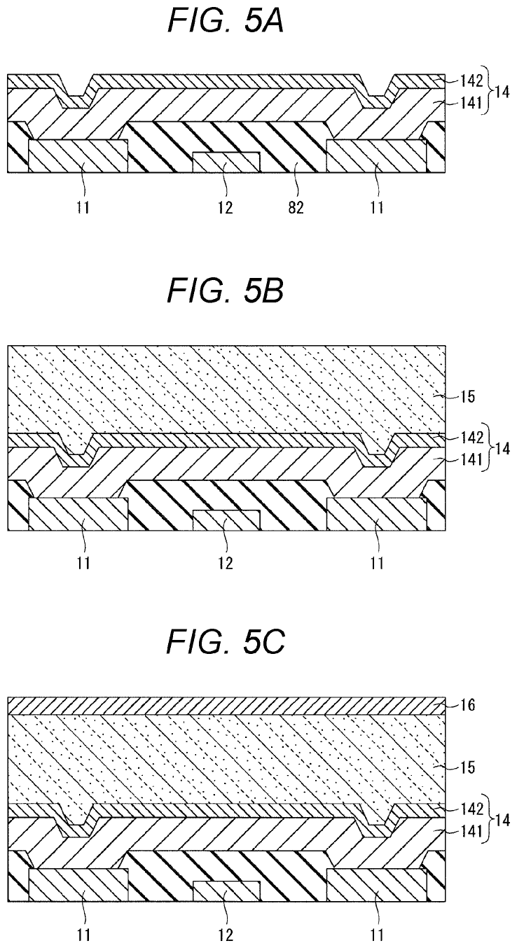

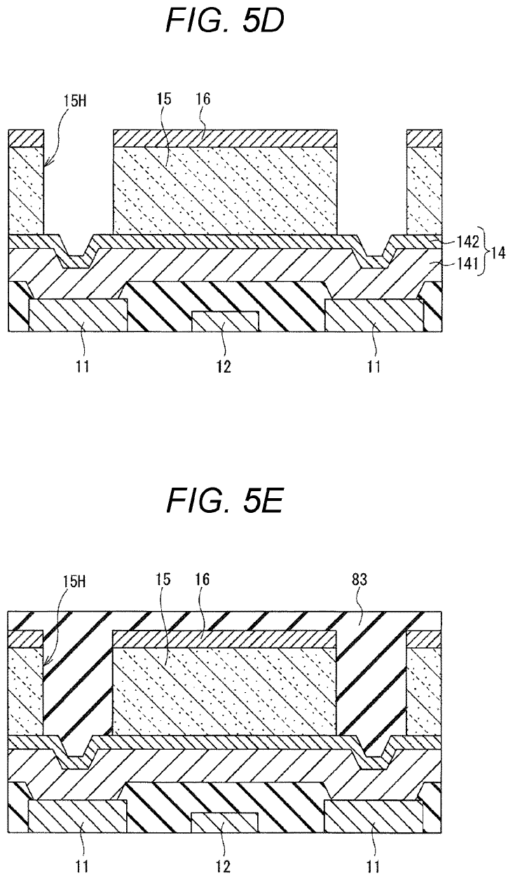

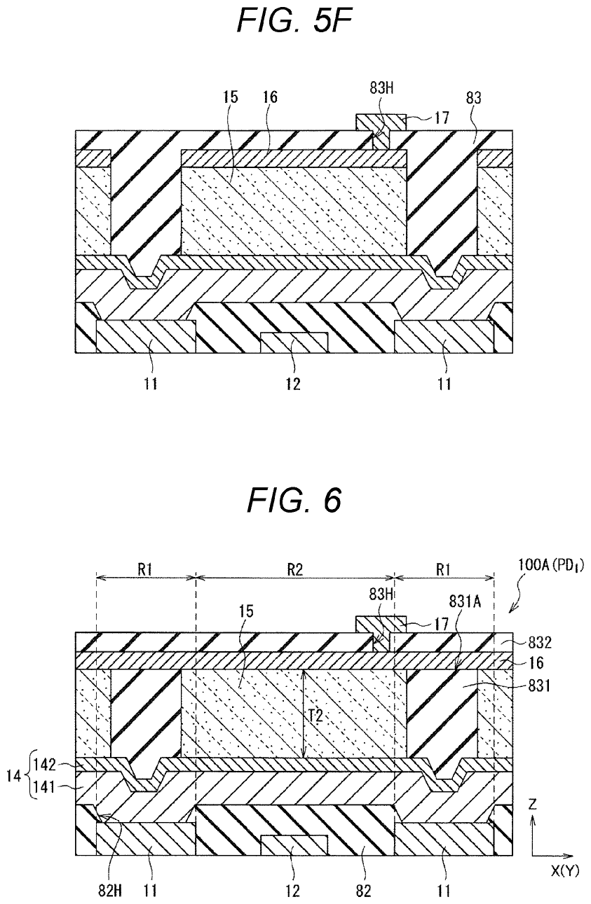

FIGS. 5A to 5F are cross-sectional views illustrating the method 2 for manufacturing the imaging device 100 according to the first embodiment of the present disclosure in order of steps. In FIG. 5A, the steps up to the step of forming the buffer layer 142 are the same as those in the manufacturing method 1 described with reference to FIGS. 4A to 41.

After the buffer layer 142 is formed, as illustrated in FIG. 5B, the manufacturing device forms the photoelectric conversion layer 15 on the buffer layer 142. Next, as illustrated in FIG. 5C, the manufacturing device forms the light-transmissive second electrode 16 on the photoelectric conversion layer 15. Next, as illustrated in FIG. 5D, the manufacturing device patterns the second electrode 16 and the photoelectric conversion layer 15 using a photolithography technique and an etching technique.

Next, as illustrated in FIG. 5E, the manufacturing device forms the insulating layer 83 on the buffer layer 142 on which the photoelectric conversion layer 15 and the second electrode 16 are formed. The insulating layer 83 is embedded in the through hole 15H.

Subsequent steps are the same as those in the manufacturing method 1. As illustrated in FIG. 5F, the manufacturing device forms the through hole 83H in the insulating layer 83 using a photolithography technique and an etching technique. Next, the manufacturing device forms a conductive layer on the insulating layer 83 in which the through hole 83H is formed, and patterns the conductive layer to form the wiring 17. Through the above steps, the imaging device 100 illustrated in FIG. 3 is completed.

In the above manufacturing method 2, the photoelectric conversion layer 15 is formed before the insulating layer 83 is formed. A film formation surface (base) of the photoelectric conversion layer 15 is flat as compared with the manufacturing method 1 because the first insulating film 831 is not disposed (see FIG. 4D). Therefore, in the manufacturing method 2 described above, the photoelectric conversion layer 15 can be easily formed as compared with the manufacturing method 1 described above.

As described above, the imaging device 100 according to the first embodiment of the present disclosure includes the photoelectric conversion layer 15 having the first surface 15A and the second surface 15B located on an opposite side to the first surface 15A, the first electrode 11 located on a side of the first surface 15A, and the second electrode 16 located on a side of the second surface 15B. In a thickness direction (for example, the Z-axis direction) of the photoelectric conversion layer 15, a region overlapping with the first electrode 11 is defined as a first region R1, and a region deviated from the first electrode 11 is defined as a second region R2. A film thickness T1 of the photoelectric conversion layer 15 in at least a part of the first region R1 is thinner than a film thickness T2 of the photoelectric conversion layer 15 in the second region R2. For example, T1 is zero.

With this configuration, the imaging device 100 can suppress photoelectric conversion and charge accumulation above the first electrode 11 even in a case where obliquely incident light is incident on a portion above the first electrode 11. As the film thickness T1 is thinner, photoelectric conversion and charge accumulation above the first electrode 11 can be more effectively suppressed. The imaging device 100 can suppress charge accumulation above the first electrode 11, and therefore can suppress deterioration in performance such as inhibition of GS driving, and can improve oblique incidence resistance of GS driving. Furthermore, in the imaging device 100, since an inflow of charges from above the first electrode 11 to the first electrode 11 is small, noise can be reduced.

Furthermore, the film thickness T2 of the photoelectric conversion layer 15 in the second region R2 can be increased regardless of the film thickness T1. Therefore, even in a case where a material having a small absorption coefficient is used for the photoelectric conversion layer 15, the film thickness T2 can be increased to increase an absorption ratio.

### Second Embodiment

In the first embodiment, the case where the second electrode 16 is not disposed in at least a part of the first region R1 has been described. However, the embodiments of the present disclosure are not limited thereto.

FIG. 6 is a cross-sectional view schematically illustrating a configuration example of a photoelectric conversion unit PD1 of an imaging device 100A according to a second embodiment of the present disclosure and a peripheral portion thereof. As illustrated in FIG. 6, in the imaging device 100A, a second electrode 16 is disposed in an entire first region R1. The second electrode 16 is disposed continuously from the first region R1 to a second region R2.

Even with such a configuration, the imaging device 100A can suppress photoelectric conversion and charge accumulation above a first electrode 11. The imaging device 100A can suppress charge accumulation above the first electrode 11, and therefore can suppress deterioration in performance such as inhibition of GS driving, and can improve oblique incidence resistance of GS driving.

### Third Embodiment

In the first embodiment, the case where the film thickness T1 of the photoelectric conversion layer 15 in at least a part of the first region R1 is zero has been described. However, the embodiments of the present disclosure are not limited thereto. In the embodiments of the present disclosure, the film thickness T1 only needs to be thinner than the film thickness T2.

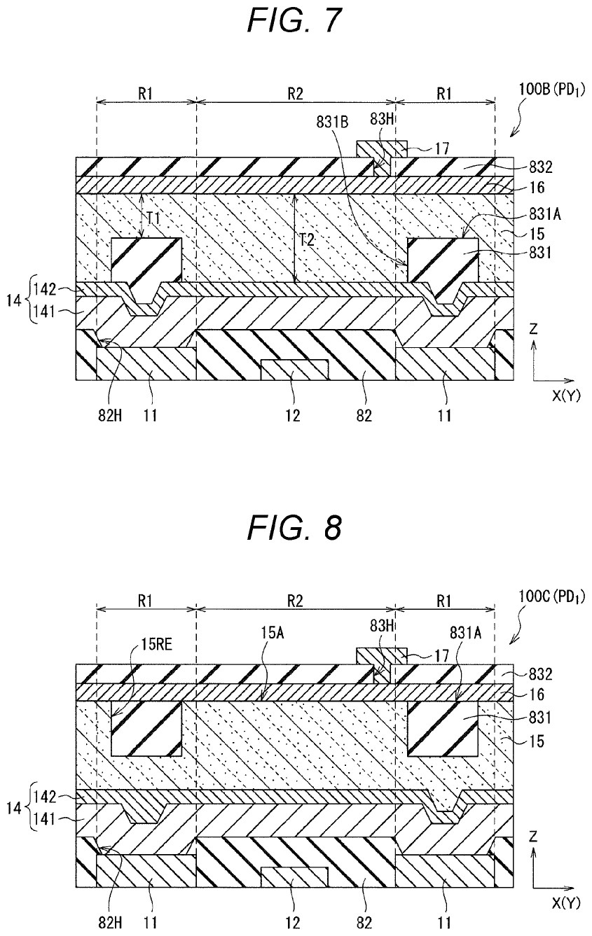

FIG. 7 is a cross-sectional view schematically illustrating a configuration example of a photoelectric conversion unit PD1 of an imaging device 100B according to a third embodiment of the present disclosure and a peripheral portion thereof. As illustrated in FIG. 7, in the imaging device 100B, a first insulating film 831 is disposed in at least a part of a first region R1. In the Z-axis direction, the first insulating film 831 is disposed between a buffer layer 142 and a photoelectric conversion layer 15.

The first insulating film 831 is not disposed in a second region R2. The photoelectric conversion layer 15 is disposed on the buffer layer 142 and covers an upper surface 831A and a side surface 831B of the first insulating film 831. Therefore, a film thickness T1 of the photoelectric conversion layer 15 in at least a part of the first region R1 is thinner than a film thickness T2 of the photoelectric conversion layer 15 in the second region R2.

Even with such a configuration, the imaging device 100B can suppress photoelectric conversion and charge accumulation above a first electrode 11. The imaging device 100B can suppress charge accumulation above the first electrode 11, and therefore can suppress deterioration in performance such as inhibition of GS driving, and can improve oblique incidence resistance of GS driving.

### Fourth Embodiment

FIG. 8 is a cross-sectional view schematically illustrating a configuration example of a photoelectric conversion unit PD1 of an imaging device 100C according to a fourth embodiment of the present disclosure and a peripheral portion thereof. As illustrated in FIG. 8, in the imaging device 100C, a photoelectric conversion layer 15 is disposed continuously on a buffer layer 142 from a first region R1 to a second region R2. Furthermore, in at least a part of the first region R1, a recess 15RE is formed on a first surface 15A of the photoelectric conversion layer 15, and a first insulating film 831 is disposed in the recess 15RE. In the Z-axis direction, the first insulating film 831 is disposed between the photoelectric conversion layer 15 and a second electrode 16.

In the second region R2, the recess 15RE is not formed in the photoelectric conversion layer 15. There is no size difference in level between an upper surface 831A of the first insulating film 831 and the first surface 15A of the photoelectric conversion layer 15, and the upper surface 831A and the first surface 15A are flush or substantially flush. The second electrode 16 is disposed continuously on the first insulating film 831 and on the photoelectric conversion layer 15. Therefore, a film thickness T1 of the photoelectric conversion layer 15 in at least a part of the first region R1 is thinner than a film thickness T2 of the photoelectric conversion layer 15 in the second region R2.

Even with such a configuration, the imaging device 100C can suppress photoelectric conversion and charge accumulation above a first electrode 11. The imaging device 100C can suppress charge accumulation above the first electrode 11, and therefore can suppress deterioration in performance such as inhibition of GS driving, and can improve oblique incidence resistance of GS driving.

### Fifth Embodiment

In the embodiments of the present disclosure, a gate electrode of a transistor may be disposed on the interlayer insulating film 81 side by side with the first electrode 11 and the third electrode 12.

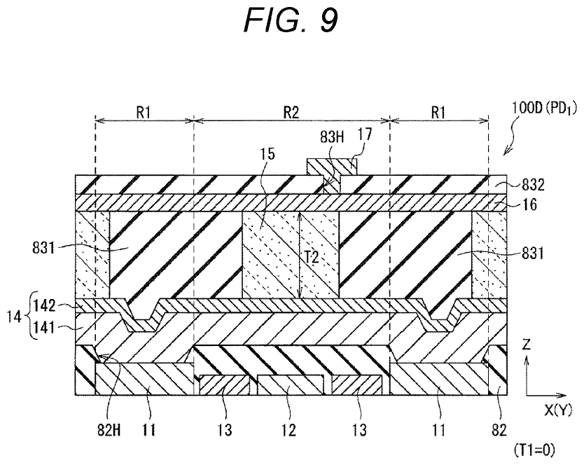

FIG. 9 is a cross-sectional view schematically illustrating a configuration example of a photoelectric conversion unit PD1 of an imaging device 100D according to a fifth embodiment of the present disclosure and a peripheral portion thereof. As illustrated in FIG. 9, in the imaging device 100D, a gate electrode 13 of a transfer transistor is disposed on an interlayer insulating film 81 side by side with a first electrode 11 and a third electrode 12. For example, the gate electrode 13 of the transfer transistor is disposed between the first electrode 11 and the third electrode 12 in the horizontal direction. Not a photoelectric conversion layer 15 but a first insulating film 831 is disposed above at least a part of the gate electrode 13 of the transfer transistor.

Even with such a configuration, the imaging device 100D can suppress photoelectric conversion and charge accumulation above a first electrode 11. The imaging device 100D can suppress charge accumulation above the first electrode 11, and therefore can suppress deterioration in performance such as inhibition of GS driving, and can improve oblique incidence resistance of GS driving.

### Sixth Embodiment

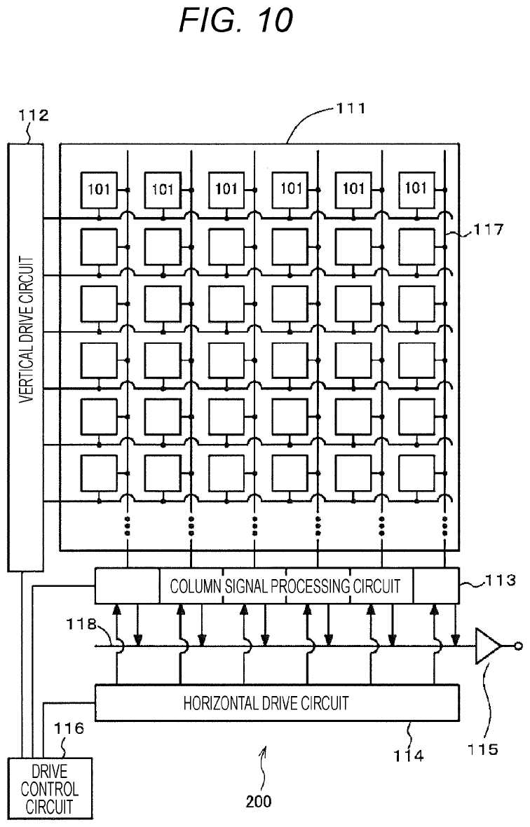

FIG. 10 is a block diagram illustrating a configuration example of an imaging device 200 according to a sixth embodiment of the present disclosure. The imaging device 200 illustrated in FIG. 10 includes an imaging region 111 in which laminated imaging elements 101 are arrayed two-dimensionally, and a vertical drive circuit 112, a column signal processing circuit 113, a horizontal drive circuit 114, an output circuit 115, a drive control circuit 116, and the like as drive circuits (peripheral circuits) of the laminated imaging elements 101.

The laminated imaging element 101 has, for example, the same structure as any one or more of the imaging devices 100 to 100D described in the first to fifth embodiments. The vertical drive circuit 112, the column signal processing circuit 113, the horizontal drive circuit 114, the output circuit 115, and the drive control circuit 116 (hereinafter, these are collectively referred to as peripheral circuits) are constituted by well-known circuits. Furthermore, the peripheral circuits may be constituted by various circuits used in a conventional CCD imaging device or CMOS imaging device. Note that in FIG. 10, the reference number “101” of the laminated imaging element 101 is displayed only in one row.

The drive control circuit 116 generates a clock signal or a control signal as a reference of actions of the vertical drive circuit 112, the column signal processing circuit 113, and the horizontal drive circuit 114 on the basis of a vertical synchronizing signal, a horizontal synchronizing signal, and a master clock. Then, the generated clock signal or control signal is input to the vertical drive circuit 112, the column signal processing circuit 113, and the horizontal drive circuit 114.

For example, the vertical drive circuit 112 is constituted by a shift register, and sequentially selects and scans the laminated imaging elements 101 in the imaging region 111 in a row unit in the vertical direction. Then, a pixel signal (image signal) based on a current (signal) generated according to the amount of light received by each of the laminated imaging elements 101 is sent to the column signal processing circuit 113 via a signal line (data output line) 117. One signal line (data output line) 117 includes, for example, one or more of the signal lines (data output lines) VSL1, VSL2, VSL3 . . . illustrated in FIG. 2.

The column signal processing circuit 113 is disposed, for example, for each column of the laminated imaging elements 101. The column signal processing circuit 113 performs signal processing such as noise removal or signal amplification on image signals output from the laminated imaging elements 101 in one row with a signal from a black reference pixel (not illustrated, but formed around an effective pixel region) for each of the imaging elements. An output stage of the column signal processing circuit 113 is connected to a horizontal signal line 118 via a horizontal selection switch (not illustrated).

The horizontal drive circuit 114 is constituted by, for example, a shift register. The horizontal drive circuit 114 sequentially outputs a horizontal scanning pulse to the above-described horizontal selection switch to sequentially select each of the column signal processing circuits 113. The selected column signal processing circuit 113 outputs a signal to the horizontal signal line 118.

The output circuit 115 performs signal processing to a signal sequentially supplied from each of the column signal processing circuits 113 via the horizontal signal line 118, and outputs the signal.

### Other Embodiments

As described above, the present disclosure has been described with reference to the embodiments and the modifications, but it should not be understood that the description and the drawings constituting a part of this disclosure limit the present disclosure. Various alternative embodiments, examples, and operation techniques will be apparent to those skilled in the art from this disclosure. For example, in the first embodiment described above, the second electrode 16 may be disposed continuously from the first surface 15A of the photoelectric conversion layer 15 to the buffer layer 142 in the first region R1 through a side surface of the photoelectric conversion layer 15.

Alternatively, in the first, second, and fifth embodiments described above, a light shielding layer may be disposed above the conductive layer 14 in the first region R1. In the third to fifth embodiments described above, a light shielding layer may be disposed on the photoelectric conversion layer 15 in the first region R1. With such a configuration, photoelectric conversion in the conductive layer 14 and the photoelectric conversion layer 15 in the first region R1 can be further suppressed.

As described above, it is a matter of course that the technology according to the present disclosure (the present technology) includes various embodiments and the like not described herein. At least one of various omissions, replacements, and changes of the components can be made without departing from the gist of the embodiments and modifications described above. Furthermore, the effects described here are merely examples, the effects of the present technology are not limited thereto, and the present technology may have other effects.

<Application Example to Electronic Apparatus>

The technology according to the present disclosure (the present technology) can be applied to various electronic apparatuses such as an imaging system including a digital still camera, a digital video camera, and the like (hereinafter, collectively referred to as a camera), a mobile device such as a mobile phone having an imaging function, and another device having an imaging function.

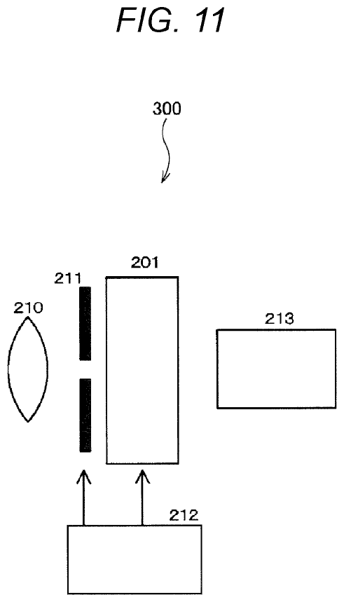

FIG. 11 is a conceptual diagram illustrating an example in which the technology according to the present disclosure (present technology) is applied to an electronic apparatus 300. As illustrated in FIG. 11, the electronic apparatus 300 is, for example, a camera, and includes a solid-state imaging device 201, an optical lens 210, a shutter device 211, a drive circuit 212, and a signal processing circuit 213. The optical lens 210 is an example of an “optical component” of the present disclosure.

Light that has passed through the optical lens 210 is incident on the solid-state imaging device 201. For example, the optical lens 210 forms an image of image light (incident light) from a subject on an imaging surface of the solid-state imaging device 201. Therefore, signal charges are accumulated in the solid-state imaging device 201 for a certain period of time. The shutter device 211 controls a light irradiation period and a light shielding period for the solid-state imaging device 201. The drive circuit 212 supplies a driving signal for controlling a transfer operation and the like of the solid-state imaging device 201 and a shutter operation of the shutter device 211. The solid-state imaging device 201 transfers a signal by a driving signal (timing signal) supplied from the drive circuit 212. The signal processing circuit 213 performs various types of signal processing. For example, the signal processing circuit 213 processes a signal output from the solid-state imaging device 201. A video signal that has been subjected to signal processing is stored in a storage medium such as a memory or is output to a monitor.

In the electronic apparatus 300, any one or more of the imaging devices 100 to 100D and 200 described above are applied to the solid-state imaging device 201. Therefore, the electronic apparatus 300 with improved performance can be obtained. Note that the electronic apparatus 300 is not limited to a camera. The electronic apparatus 300 may be a mobile device such as a mobile phone having an imaging function, or another device having an imaging function.

<Application Example to Endoscopic Surgical System>

The technology according to the present disclosure (the present technology) can be applied to various products. For example, the technology according to the present disclosure may be applied to an endoscopic surgical system.

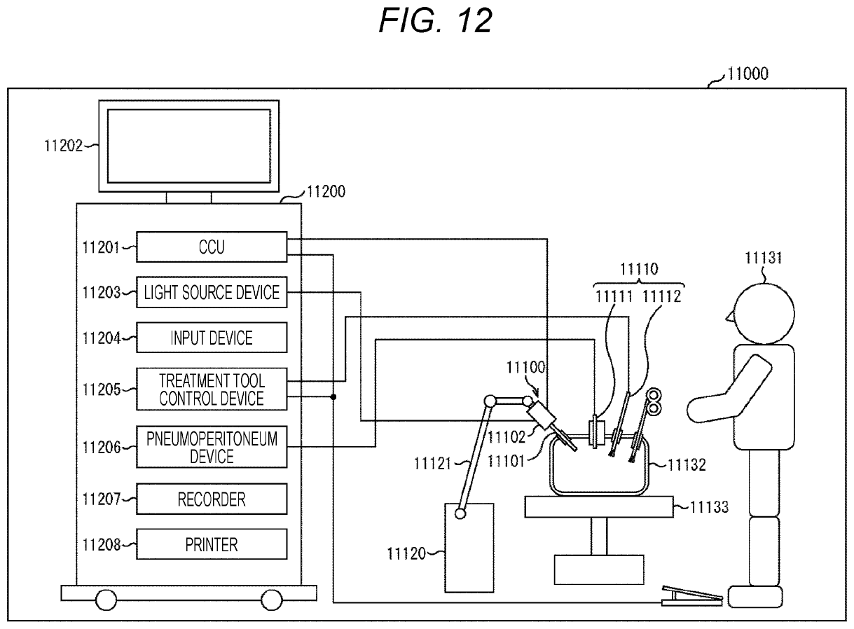

FIG. 12 is a diagram illustrating an example of a schematic configuration of an endoscopic surgical system to which the technology according to the present disclosure (the present technology) can be applied.

FIG. 12 illustrates a situation in which a surgeon (physician) 11131 is performing surgery on a patient 11132 on a patient bed 11133 using an endoscopic surgical system 11000. As illustrated in the drawing, the endoscopic surgical system 11000 includes an endoscope 11100, another surgical tool 11110 such as a pneumoperitoneum tube 11111 or an energy treatment tool 11112, a support arm device 11120 for supporting the endoscope 11100, and a cart 11200 on which various devices for endoscopic surgery are mounted.

The endoscope 11100 includes a lens barrel 11101 to be inserted into a body cavity of the patient 11132 in a region of a predetermined length from a tip thereof, and a camera head 11102 connected to a proximal end of the lens barrel 11101. In the illustrated example, the endoscope 11100 configured as a so-called rigid mirror including the rigid lens barrel 11101 is illustrated, but the endoscope 11100 may be configured as a so-called flexible mirror including a flexible lens barrel.

At the tip of the lens barrel 11101, an opening into which an objective lens is fitted is disposed. A light source device 11203 is connected to the endoscope 11100. Light generated by the light source device 11203 is guided to the tip of the lens barrel by a light guide extended inside the lens barrel 11101, and is emitted toward an observation target in a body cavity of the patient 11132 via the objective lens. Note that the endoscope 11100 may be a forward-viewing endoscope, an oblique-viewing endoscope, or a side-viewing endoscope.

An optical system and an imaging element are disposed inside the camera head 11102. Reflected light (observation light) from an observation target is converged on the imaging element by the optical system. The observation light is photoelectrically converted by the imaging element, and an electric signal corresponding to the observation light, that is, an image signal corresponding to an observation image is generated. The image signal is transmitted as RAW data to a camera control unit (CCU) 11201.

The CCU 11201 includes a central processing unit (CPU), a graphics processing unit (GPU), and the like, and integrally controls operations of the endoscope 11100 and the display device 11202. Moreover, the CCU 11201 receives an image signal from the camera head 11102, and performs, on the image signal, various image processing for displaying an image based on the image signal, such as development processing (demosaic processing), for example.

The display device 11202 displays an image based on an image signal subjected to image processing by the CCU 11201 under the control of the CCU 11201.

The light source device 11203 includes a light source such as a light emitting diode (LED), for example, and supplies irradiation light for imaging a surgical site or the like to the endoscope 11100.

An input device 11204 is an input interface to the endoscopic surgical system 11000. A user can input various kinds of information and instructions to the endoscopic surgical system 11000 via the input device 11204. For example, the user inputs an instruction or the like to change imaging conditions (type of irradiation light, magnification, focal length, and the like) by the endoscope 11100.

A treatment tool control device 11205 controls driving of the energy treatment tool 11112 for cauterizing and cutting a tissue, sealing a blood vessel, or the like. A pneumoperitoneum device 11206 feeds a gas into a body cavity via the pneumoperitoneum tube 11111 in order to inflate the body cavity of the patient 11132 for the purpose of securing a field of view by the endoscope 11100 and securing a working space of a surgeon. A recorder 11207 is a device capable of recording various kinds of information regarding surgery. A printer 11208 is a device capable of printing various kinds of information regarding surgery in various formats such as a text, an image, and a graph.

Note that the light source device 11203 for supplying irradiation light used for imaging a surgical site to the endoscope 11100 may include an LED, a laser light source, or a white light source constituted by a combination thereof, for example. In a case where the white light source is constituted by a combination of RGB laser light sources, the output intensity and the output timing of each color (each wavelength) can be controlled with high precision, and therefore adjustment of a white balance of an imaged image can be performed by the light source device 11203. Furthermore, in this case, by irradiating an observation target with laser light from each of the RGB laser light sources in a time division manner and controlling driving of an imaging element of the camera head 11102 in synchronization with the irradiation timing, it is also possible to image an image corresponding to each of RGB in a time division manner. According to this method, a color image can be obtained without disposing a color filter in the imaging element.

Furthermore, driving of the light source device 11203 may be controlled so as to change the intensity of light output at predetermined time intervals. By controlling driving of the imaging element of the camera head 11102 in synchronization with the timing of the change of the intensity of the light to acquire an image in a time division manner and synthesizing the image, a high dynamic range image without so-called blocked up shadows or blown out highlights can be generated.

Furthermore, the light source device 11203 may be configured so as to be able to supply light in a predetermined wavelength band corresponding to special light observation. In the special light observation, for example, by irradiation with light in a narrower band than irradiation light (in other words, white light) at the time of ordinary observation using wavelength dependency of light absorption in a body tissue, a predetermined tissue such as a blood vessel of a mucosal surface layer is imaged at a high contrast, that is, so-called narrow band imaging is performed. Alternatively, in the special light observation, fluorescence observation for obtaining an image by fluorescence generated by irradiation with excitation light may be performed. In the fluorescence observation, it is possible to observe fluorescence from a body tissue (autofluorescence observation) by irradiating the body tissue with excitation light, or to obtain a fluorescent image by injecting a reagent such as indocyanine green (ICG) into a body tissue and irradiating the body tissue with excitation light corresponding to a fluorescence wavelength of the reagent, for example. The light source device 11203 can be configured so as to be able to supply narrow band light and/or excitation light corresponding to such special light observation.

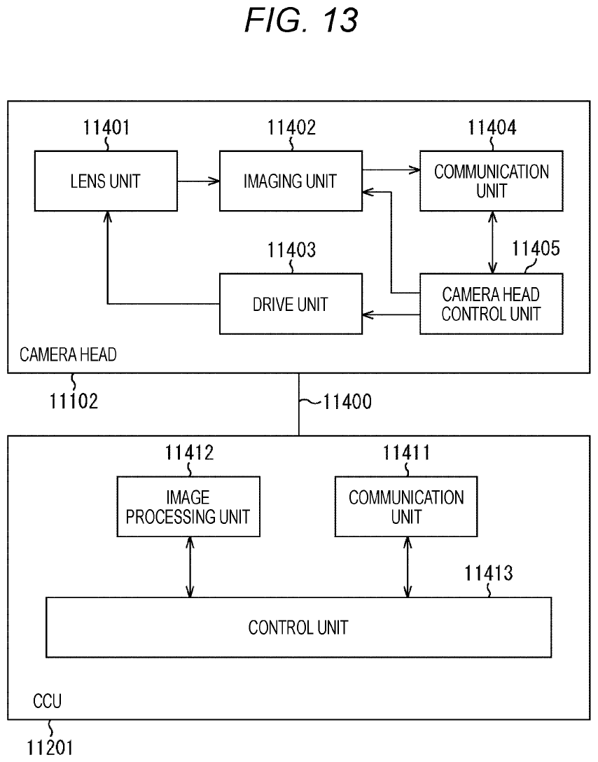

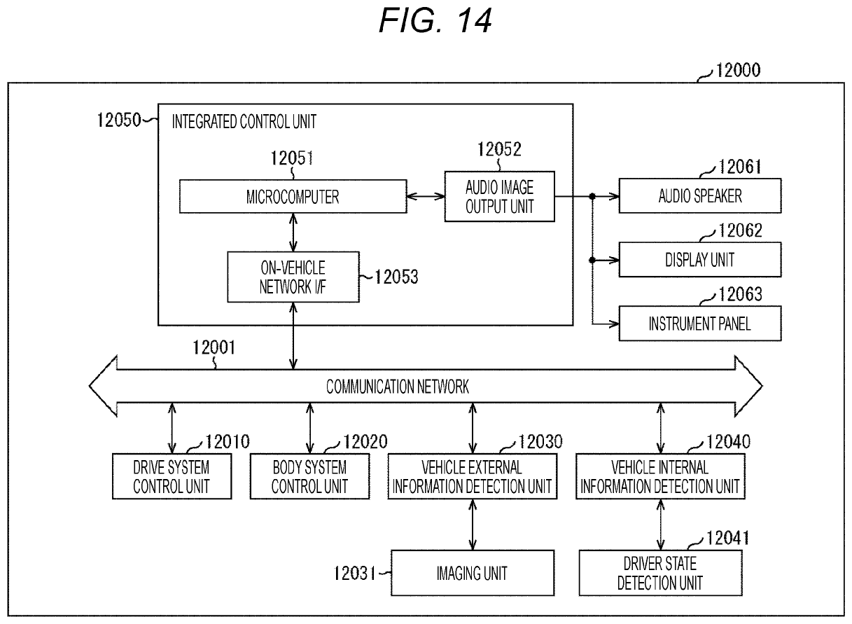

FIG. 13 is a block diagram illustrating examples of functional configurations of the camera head 11102 and the CCU 11201 illustrated in FIG. 12.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system disposed at a connecting portion with the lens barrel 11101. Observation light taken in from a tip of the lens barrel 11101 is guided to the camera head 11102 and is incident on the lens unit 11401. The lens unit 11401 includes a combination of a plurality of lenses including a zoom lens and a focus lens.

The imaging unit 11402 includes an imaging element. The imaging unit 11402 may include one imaging element (so-called single plate type) or a plurality of imaging elements (so-called multiplate type). In a case where the imaging unit 11402 includes multiplate type imaging elements, for example, an image signal corresponding to each of RGB may be generated by each imaging element, and a color image may be obtained by synthesizing these image signals. Alternatively, the imaging unit 11402 may include a pair of imaging elements for acquiring an image signal for each of the right eye and the left eye corresponding to three-dimensional (3D) display. By performing the 3D display, the surgeon 11131 can grasp the depth of a living tissue in a surgical site more accurately. Note that in a case where the imaging unit 11402 includes multiplate type imaging elements, a plurality of lens units 11401 can be disposed corresponding to the respective imaging elements.

Furthermore, the imaging unit 11402 is not necessarily disposed in the camera head 11102. For example, the imaging unit 11402 may be disposed just behind an objective lens inside the lens barrel 11101.

The drive unit 11403 includes an actuator, and moves a zoom lens and a focus lens of the lens unit 11401 by a predetermined distance along an optical axis under control of the camera head control unit 11405. Therefore, the magnification and the focus of an image imaged by the imaging unit 11402 can be appropriately adjusted.

The communication unit 11404 includes a communication device for transmitting and receiving various kinds of information to and from the CCU 11201. The communication unit 11404 transmits an image signal obtained from the imaging unit 11402 as RAW data to the CCU 11201 via the transmission cable 11400.

Furthermore, the communication unit 11404 receives a control signal for controlling driving of the camera head 11102 from the CCU 11201, and supplies the control signal to the camera head control unit 11405. The control signal includes information regarding imaging conditions such as information indicating designation of a frame rate of an imaged image, information indicating designation of an exposure value at the time of imaging, and/or information indicating designation of the magnification and the focus of an imaged image, for example.

Note that the imaging conditions such as the above-described frame rate, exposure value, magnification, and focus may be appropriately designated by a user, or may be automatically set by the control unit 11413 of the CCU 11201 on the basis of an acquired image signal. In the latter case, the endoscope 11100 has a so-called auto exposure (AE) function, a so-called auto focus (AF) function, and a so-called auto white balance (AWB) function.

The camera head control unit 11405 controls driving of the camera head 11102 on the basis of a control signal from the CCU 11201 received via the communication unit 11404.

The communication unit 11411 includes a communication device for transmitting and receiving various kinds of information to and from the camera head 11102. The communication unit 11411 receives an image signal transmitted from the camera head 11102 via the transmission cable 11400.

Furthermore, the communication unit 11411 transmits a control signal for controlling driving of the camera head 11102 to the camera head 11102. The image signal and the control signal can be transmitted by electric communication, optical communication, or the like.

The image processing unit 11412 performs various kinds of image processing on the image signal which is RAW data transmitted from the camera head 11102.

The control unit 11413 performs various kinds of control concerning imaging of a surgical site or the like by the endoscope 11100 and display of an imaged image obtained by imaging a surgical site or the like. For example, the control unit 11413 generates a control signal for controlling driving of the camera head 11102.

Furthermore, the control unit 11413 causes the display device 11202 to display an imaged image of a surgical site or the like on the basis of an image signal subjected to image processing by the image processing unit 11412. In this case, the control unit 11413 may recognize various objects in the imaged image using various image recognition techniques. For example, by detecting the shape, color, and the like of an edge of an object included in the imaged image, the control unit 11413 can recognize a surgical tool such as forceps, a specific living body part, bleeding, a mist at the time of using the energy treatment tool 11112, and the like. When the display device 11202 displays the imaged image, the control unit 11413 may cause the display device 11202 to superimpose and display various kinds of surgical support information on the image of the surgical site using the recognition result. The surgical support information is superimposed and displayed, and presented to the surgeon 11131. This makes it possible to reduce a burden on the surgeon 11131 and makes it possible for the surgeon 11131 to reliably perform surgery.

The transmission cable 11400 connecting the camera head 11102 to the CCU 11201 is an electric signal cable corresponding to communication of an electric signal, an optical fiber corresponding to optical communication, or a composite cable thereof.

Here, in the illustrated example, communication is performed by wire using the transmission cable 11400, but communication between the camera head 11102 and the CCU 11201 may be performed wirelessly.

An example of the endoscopic surgical system to which the technology according to the present disclosure can be applied has been described above. The technology according to the present disclosure can be applied to the endoscope 11100, the imaging unit 11402 of the camera head 11102, the image processing unit 11412 of the CCU 11201, and the like among the above-described configurations. Specifically, any one or more of the imaging devices 100 to 100D and 200 described above can be applied to the imaging unit 10402. By applying the technology according to the present disclosure to the endoscope 11100, the imaging unit 11402 of the camera head 11102, the image processing unit 11412 of the CCU 11201, and the like, a clearer image of a surgical site can be obtained, and therefore a surgeon can reliably confirm the surgical site. Furthermore, by applying the technology according to the present disclosure to the endoscope 11100, the imaging unit 11402 of the camera head 11102, the image processing unit 11412 of the CCU 11201, and the like, an image of a surgical site can be obtained with lower latency, and therefore, a surgeon can perform treatment with a feeling similar to that in a case where the surgeon performs tactile observation of the surgical site.

Note that the endoscopic surgical system has been described as an example here. However, the technology according to the present disclosure may also be applied to, for example, a microscopic surgery system or the like.

<Application Example to Mobile Body>

The technology according to the present disclosure (the present technology) can be applied to various products. For example, the technology according to the present disclosure may be achieved as an apparatus mounted on any type of mobile body such as an automobile, an electric vehicle, a hybrid electric vehicle, a motorcycle, a bicycle, a personal mobility, an airplane, a drone, a ship, or a robot.

FIG. 14 is a block diagram illustrating an example of a schematic configuration of a vehicle control system which is an example of a mobile body control system to which the technology according to the present disclosure can be applied.

A vehicle control system 12000 includes a plurality of electronic control units connected to one another via a communication network 12001. In the example illustrated in FIG. 14, the vehicle control system 12000 includes a drive system control unit 12010, a body system control unit 12020, a vehicle external information detection unit 12030, a vehicle internal information detection unit 12040, and an integrated control unit 12050. Furthermore, as a functional configuration of the integrated control unit 12050, a microcomputer 12051, an audio image output unit 12052, and an on-vehicle network interface (I/F) 12053 are illustrated.

The drive system control unit 12010 controls an operation of a device related to a drive system of a vehicle according to various programs. For example, the drive system control unit 12010 functions as a control device of a driving force generating device for generating a driving force of a vehicle such as an internal combustion engine or a driving motor, a driving force transmitting mechanism for transmitting a driving force to wheels, a steering mechanism for adjusting a rudder angle of a vehicle, a braking device for generating a braking force of a vehicle, or the like.

The body system control unit 12020 controls operations of various devices mounted on a vehicle body according to various programs. For example, the body system control unit 12020 functions as a control device of a keyless entry system, a smart key system, a power window device, or various lamps such as a head lamp, a back lamp, a brake lamp, a turn indicator, and a fog lamp. In this case, to the body system control unit 12020, a radio wave transmitted from a portable device substituted for a key or signals of various switches can be input. The body system control unit 12020 receives input of the radio wave or signals and controls a door lock device, a power window device, a lamp, and the like of a vehicle.

The vehicle external information detection unit 12030 detects information outside a vehicle on which the vehicle control system 12000 is mounted. For example, to the vehicle external information detection unit 12030, an imaging unit 12031 is connected. The vehicle external information detection unit 12030 causes the imaging unit 12031 to image an image outside a vehicle and receives an imaged image. The vehicle external information detection unit 12030 may perform object detection processing or distance detection processing of a person, a car, an obstacle, a sign, a character on a road surface, or the like on the basis of the received image.

The imaging unit 12031 is a light sensor for receiving light and outputting an electric signal corresponding to the amount of light received. The imaging unit 12031 can output an electric signal as an image or output the electric signal as distance measurement information. Furthermore, the light received by the imaging unit 12031 may be visible light or invisible light such as infrared light.

The vehicle internal information detection unit 12040 detects information inside a vehicle. To the vehicle internal information detection unit 12040, for example, a driver state detection unit 12041 for detecting the state of a driver is connected. The driver state detection unit 12041 includes, for example, a camera for imaging a driver. The vehicle internal information detection unit 12040 may calculate the degree of fatigue or the degree of concentration of a driver or may determine whether or not the driver is dozing off on the basis of detection information input from the driver state detection unit 12041.

The microcomputer 12051 can calculate a control target value of a driving force generating device, a steering mechanism, or a braking device on the basis of information inside and outside a vehicle, acquired by the vehicle external information detection unit 12030 or the vehicle internal information detection unit 12040, and can output a control command to the drive system control unit 12010. For example, the microcomputer 12051 can perform cooperative control aiming at realizing a function of advanced driver assistance system (ADAS) including collision avoidance or impact mitigation of a vehicle, following travel based on inter-vehicle distance, vehicle speed maintenance travel, vehicle collision warning, vehicle lane departure warning, and the like.

Furthermore, the microcomputer 12051 can perform cooperative control aiming at, for example, automatic driving that autonomously travels without depending on driver's operation by controlling a driving force generating device, a steering mechanism, a braking device, or the like on the basis of information around a vehicle, acquired by the vehicle external information detection unit 12030 or the vehicle internal information detection unit 12040.

Furthermore, the microcomputer 12051 can output a control command to the body system control unit 12020 on the basis of vehicle external information acquired by the vehicle external information detection unit 12030. For example, the microcomputer 12051 can perform cooperative control aiming at antiglare such as switching from high beam to low beam by controlling a headlamp according to the position of a preceding vehicle or an oncoming vehicle detected by the vehicle external information detection unit 12030.

The audio image output unit 12052 transmits at least one of an audio output signal or an image output signal to an output device capable of visually or audibly notifying a passenger of a vehicle or the outside of the vehicle of information. In the example of FIG. 14, as the output device, an audio speaker 12061, a display unit 12062, and an instrument panel 12063 are illustrated. The display unit 12062 may include an on-board display and/or a head-up display, for example.

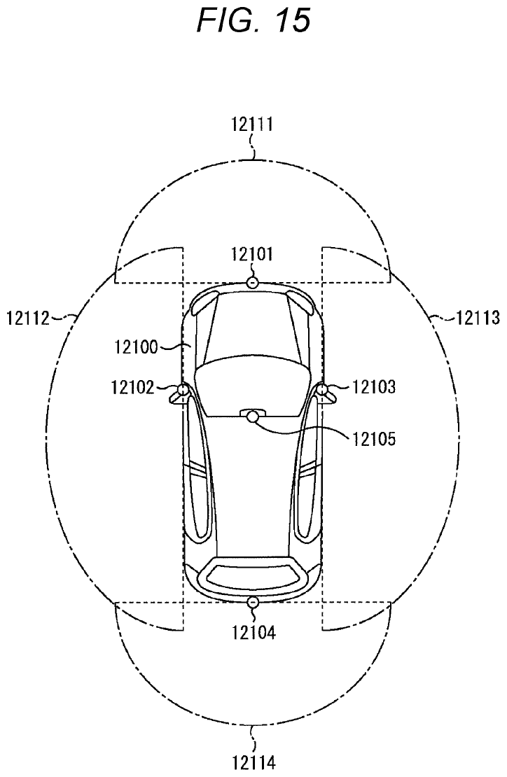

FIG. 15 is a diagram illustrating an example of an installation position of the imaging unit 12031.

In FIG. 15, the vehicle 12100 includes imaging units 12101, 12102, 12103, 12104, and 12105 as the imaging unit 12031.

The imaging units 12101, 12102, 12103, 12104, and 12105 are disposed, for example, in a front nose, a side mirror, a rear bumper, and a back door of the vehicle 12100, in an upper portion of a front glass in a passenger compartment, and the like. The imaging unit 12101 disposed in a front nose and the imaging unit 12105 disposed in an upper portion of a front glass in a passenger compartment mainly acquire images in front of the vehicle 12100. The imaging units 12102 and 12103 disposed in side mirrors mainly acquire images on sides of the vehicle 12100. The imaging unit 12104 disposed in a rear bumper or a back door mainly acquires an image behind the vehicle 12100. The front images acquired by the imaging units 12101 and 12105 are mainly used for detecting a preceding vehicle, a pedestrian, an obstacle, a traffic signal, a traffic sign, a lane, or the like.

Note that FIG. 15 illustrates examples of imaging ranges of the imaging units 12101 to 12104. An imaging range 12111 indicates an imaging range of the imaging unit 12101 disposed in a front nose. Imaging ranges 12112 and 12113 indicate imaging ranges of the imaging units 12102 and 12103 disposed in side mirrors, respectively. An imaging range 12114 indicates an imaging range of the imaging unit 12104 disposed in a rear bumper or a back door. For example, by superimposing image data imaged by the imaging units 12101 to 12104 on one another, an overhead view image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be an imaging element having pixels for phase difference detection.

For example, the microcomputer 12051 determines a distance to each three-dimensional object in the imaging range 12111 to 12114 and a temporal change (relative speed with respect to the vehicle 12100) of the distance on the basis of the distance information obtained from the imaging units 12101 to 12104, and can thereby particularly extract a three-dimensional object which is the nearest three-dimensional object on a traveling path of the vehicle 12100 and is traveling at a predetermined speed (for example, 0 km/h or more) in substantially the same direction as the vehicle 12100 as a preceding vehicle. Moreover, the microcomputer 12051 can set an inter-vehicle distance to be secured in advance in front of the preceding vehicle, and can perform automatic brake control (including following stop control), automatic acceleration control (including following start control), and the like. In this way, it is possible to perform cooperative control aiming at, for example, automatic driving that autonomously travels without depending on driver's operation.

For example, the microcomputer 12051 classifies three-dimensional object data related to a three-dimensional object into a two-wheeled vehicle, a regular vehicle, a large vehicle, a pedestrian, and another three-dimensional object such as a telegraph pole on the basis of the distance information obtained from the imaging units 12101 to 12104 and extracts data, and can use the extracted data for automatic avoidance of an obstacle. For example, the microcomputer 12051 identifies an obstacle around the vehicle 12100 as an obstacle that a driver of the vehicle 12100 can see and an obstacle that is difficult to see. Then, the microcomputer 12051 judges a collision risk indicating a risk of collision with each obstacle. When the collision risk is higher than a set value and there is a possibility of collision, the microcomputer 12051 can perform driving assistance for avoiding collision by outputting an alarm to a driver via the audio speaker 12061 or the display unit 12062, or performing forced deceleration or avoiding steering via the drive system control unit 12010.

At least one of the imaging units 12101 to 12104 may be an infrared camera for detecting an infrared ray. For example, the microcomputer 12051 can recognize a pedestrian by determining whether or not a pedestrian exists in imaged images of the imaging units 12101 to 12104. Such recognition of a pedestrian is performed by, for example, a procedure of extracting characteristic points in imaged images of the imaging units 12101 to 12104 as infrared cameras and a procedure of performing pattern matching processing on a series of characteristic points indicating an outline of an object and determining whether or not a pedestrian exists. If the microcomputer 12051 determines that a pedestrian exists in imaged images of the imaging units 12101 to 12104 and recognizes a pedestrian, the audio image output unit 12052 controls the display unit 12062 such that the display unit 12062 superimposes and displays a rectangular contour line for emphasis on the recognized pedestrian. Furthermore, the audio image output unit 12052 may control the display unit 12062 such that the display unit 12062 displays an icon or the like indicating a pedestrian at a desired position.

An example of the vehicle control system to which the technology according to the present disclosure can be applied has been described above. The technology according to the present disclosure can be applied to the imaging unit 12031 and the like in the above-described configurations. Specifically, any one or more of the imaging devices 100 to 100D and 200 described above can be applied to the imaging unit 12031. By applying the technology according to the present disclosure to the imaging unit 12031, a more easily viewable imaged image can be obtained. Therefore, fatigue of a driver can be reduced.

Note that the present disclosure can have the following configurations.

(1) An imaging device including:

a photoelectric conversion layer having a first surface and a second surface located on an opposite side to the first surface;

a first electrode located on a side of the first surface; and

a second electrode located on a side of the second surface, in which

in a thickness direction of the photoelectric conversion layer, when a region overlapping with the first electrode is defined as a first region, and a region deviating from the first electrode is defined as a second region,

a first film thickness of the photoelectric conversion layer in at least a part of the first region is thinner than a second film thickness of the photoelectric conversion layer in the second region.

(2) The imaging device according to (1), in which the first film thickness is zero.

(3) The imaging device according to (1) or (2), further including

a conductive layer in contact with the photoelectric conversion layer and the first electrode.

(4) The imaging device according to (3), in which

the conductive layer includes:

a semiconductor layer in contact with the first electrode; and

a buffer layer that is laminated on the semiconductor layer and is in contact with the photoelectric conversion layer.

(5) The imaging device according to (3) or (4), further including

a first insulating layer that is disposed in the first region and is in contact with the photoelectric conversion layer.

(6) The imaging device according to (5), in which

the first insulating layer is disposed between the conductive layer and the photoelectric conversion layer.

(7) The imaging device according to (5), in which

the first insulating layer is disposed between the photoelectric conversion layer and the second electrode.

(8) The imaging device according to any one of (3) to (7), further including:

a third electrode disposed on an opposite side to the photoelectric conversion layer with the conductive layer interposed between the third electrode and the photoelectric conversion layer; and

a second insulating layer disposed between the third electrode and the conductive layer, in which

the third electrode overlaps with the photoelectric conversion layer in the thickness direction.

(9) An electronic apparatus including:

an optical component;

an imaging device on which light that has passed through the optical component is incident; and

a signal processing circuit that processes a signal output from the imaging device, in which

the imaging device includes:

a photoelectric conversion layer having a first surface and a second surface located on an opposite side to the first surface;

a first electrode located on a side of the first surface; and

a second electrode located on a side of the second surface, and

in a thickness direction of the photoelectric conversion layer, when a region overlapping with the first electrode is defined as a first region, and a region deviating from the first electrode is defined as a second region,

a first film thickness of the photoelectric conversion layer in at least a part of the first region is thinner than a second film thickness of the photoelectric conversion layer in the second region.

### REFERENCE SIGNS LIST

11 First electrode
12 Third electrode
13 Gate electrode
14 Conductive layer
15 Photoelectric conversion layer
15A First surface
15B Second surface
15H Through hole
15RE Recess
16 Second electrode
17 Wiring
41 n-Type semiconductor region
42, 44, 73 p⁺ Layer
43 n-Type semiconductor region
45, 46, 51, 52, 53 Gate portion
45C, 46C Region
46A Transfer channel
51A, 52A, 53A Channel forming region
51B, 52B, 53B Drain region
51C, 52C, 53C Source region
61 Contact hole portion
62 Wiring layer
63, 64 Pad portion
65, 66 Connection hole
70 Semiconductor substrate
70A Front surface
70B Back surface
71 Element isolation region
72 Oxide film
74 HfO₂ film
75 Insulating film
76, 81 Interlayer insulating film
81 Interlayer insulating film
82, 83 Insulating layer
82H, 83H Through hole
90 On-chip micro lens
100, 100A, 100B, 100C, 100D, 200 Imaging device
101 Laminated imaging element
111 Imaging region
112 Vertical drive circuit
113 Column signal processing circuit
114 Horizontal drive circuit
115 Output circuit
116 Drive control circuit
117 Signal line (data output line)
118 Horizontal signal line
141 Semiconductor layer
142 Buffer layer
201 Solid-state imaging device
210 Optical lens
211 Shutter device
212 Drive circuit
213 Signal processing circuit
300 Electronic apparatus
831 First insulating film
831A Upper surface
831B Side surface
832 Second insulating film
10402 Imaging unit
11000 Endoscopic surgical system
11100 Endoscope
11101 Lens barrel
11102 Camera head
11110 Surgical tool
11111 Pneumoperitoneum tube
11112 Energy treatment tool
11120 Support arm device
11131 Surgeon (physician)
11132 Patient
11133 Patient bed
11200 Cart
11201 Camera control unit (CCU)
11202 Display device
11203 Light source device
11204 Input device
11205 Treatment tool control device
11206 Pneumoperitoneum device
11207 Recorder
11208 Printer
11400 Transmission cable
11401 Lens unit
11402 Imaging unit
11403 Drive unit
11404 Communication unit
11405 Camera head control unit
11411 Communication unit
11412 Image processing unit
11413 Control unit
12000 Vehicle control system
12001 Communication network
12010 Drive system control unit
12020 Body system control unit
12030 Vehicle external information detection unit
12031 Imaging unit
12040 Vehicle internal information detection unit
12041 Driver state detection unit
12050 Integrated control unit
12051 Microcomputer
12052 Audio image output unit
12061 Audio speaker
12062 Display unit
12063 Instrument panel
12100 Vehicle
12101, 12102, 12103, 12104, 12105 Imaging unit
12111, 12112, 12113, 12114 Imaging range
FD1 First floating diffusion layer
FD2 Second floating diffusion layer
FD3 Third floating diffusion layer
PD1, PD2, PD3 Photoelectric conversion unit
R1 First region
R2 Second region
T1, T2 Film thickness
TG2, TG3 Transfer gate line
TR1amp, TR2amp, TR3amp Amplification transistor
TR1rst, TR2rst, TR3rst Reset transistor
TR1sel, TR2sel, TR3sel Selection transistor
TR2trs, TR3trs Transfer transistor
VDD Power source
VOA Wiring
VSL1, VSL2, VSL3 Signal line (data output line)

1. An imaging device comprising:
a photoelectric conversion layer having a first surface and a second surface located on an opposite side to the first surface;
a first electrode located on a side of the first surface; and
a second electrode located on a side of the second surface, wherein
in a thickness direction of the photoelectric conversion layer, when a region overlapping with the first electrode is defined as a first region, and a region deviating from the first electrode is defined as a second region,
a first film thickness of the photoelectric conversion layer in at least a part of the first region is thinner than a second film thickness of the photoelectric conversion layer in the second region.

2. The imaging device according to claim 1, wherein the first film thickness is zero.

3. The imaging device according to claim 1, further comprising a conductive layer in contact with the photoelectric conversion layer and the first electrode.

4. The imaging device according to claim 3, wherein
the conductive layer includes:
a semiconductor layer in contact with the first electrode; and
a buffer layer that is laminated on the semiconductor layer and is in contact with the photoelectric conversion layer.

5. The imaging device according to claim 3, further comprising a first insulating layer that is disposed in the first region and is in contact with the photoelectric conversion layer.

6. The imaging device according to claim 5, wherein the first insulating layer is disposed between the conductive layer and the photoelectric conversion layer.

7. The imaging device according to claim 5, wherein the first insulating layer is disposed between the photoelectric conversion layer and the second electrode.

8. The imaging device according to claim 3, further comprising:
a third electrode disposed on an opposite side to the photoelectric conversion layer with the conductive layer interposed between the third electrode and the photoelectric conversion layer; and
a second insulating layer disposed between the third electrode and the conductive layer, wherein
the third electrode overlaps with the photoelectric conversion layer in the thickness direction.

9. An electronic apparatus comprising:
an optical component;
an imaging device on which light that has passed through the optical component is incident; and
a signal processing circuit that processes a signal output from the imaging device, wherein
the imaging device includes:
a photoelectric conversion layer having a first surface and a second surface located on an opposite side to the first surface;
a first electrode located on a side of the first surface; and
a second electrode located on a side of the second surface, and
in a thickness direction of the photoelectric conversion layer, when a region overlapping with the first electrode is defined as a first region, and a region deviating from the first electrode is defined as a second region,
a first film thickness of the photoelectric conversion layer in at least a part of the first region is thinner than a second film thickness of the photoelectric conversion layer in the second region.
